(19) United States
(12) Patent Application Publication
(10) Pub. No.: US 2022/0010186 A1
(43) Pub. Date: Jan. 13, 2022

(54) HEAT TRANSFER MEDIUM AND HEAT TRANSFER SYSTEM USING SAME

(71) Applicants: DENSO CORPORATION, Kariya-city (JP); TANIKAWA YUKA KOGYO CO., LTD., Yokohama-shi (JP)

(72) Inventors: Takuya FUSE, Kariya-city (JP); Kouji INAGAKI, Kariya-city (JP); Kenji NAKAMURA, Kariya-city (JP); Teru YAMADA, Yokohama-shi (JP); Kazumi SUZUKI, Yokohama-shi (JP)

(21) Appl. No.: 17/484,266

(22) Filed: Sep. 24, 2021

Related U.S. Application Data
(63) Continuation of application No. PCT/JP2020/012996, filed on Mar. 24, 2020.

(30) Foreign Application Priority Data
Mar. 26, 2019 (JP) 2019-058287
Mar. 26, 2019 (JP) 2019-058288
Mar. 26, 2019 (JP) 2019-058289
Mar. 26, 2019 (JP) 2019-058290

(51) Int. Cl. C09K 5/10; H05K 7/20

(52) U.S. Cl. CPC C09K 5/10; H05K 7/20218

(57) ABSTRACT

A heat transfer medium is used for a heat transfer system configured to transfer a cold of a refrigerant circulating through a refrigeration cycle device to an electric device. The heat transfer medium includes water and a lower alcohol that is at least one of methanol or ethanol.

### CROSS REFERENCE TO RELATED APPLICATION

The present application is a continuation application of International Patent Application No. PCT/JP2020/012996 filed on Mar. 24, 2020, which designated the U.S. and claims the benefit of priority from Japanese Patent Application No. 2019-058287 filed on Mar. 26, 2019, Japanese Patent Application No. 2019-058288 filed on Mar. 26, 2019, and Japanese Patent Application No. 2019-058289 filed on Mar. 26, 2019, and Japanese Patent Application No. 2019-058290 filed on Mar. 26, 2019. The entire disclosures of all of the above applications are incorporated herein by reference.

### TECHNICAL FIELD

The present disclosure relates to a heat transfer medium and a heat transfer system configured to transfer heat with the heat transfer medium.

### BACKGROUND

A device cools a low-temperature cooling water by exchanging heat between a refrigerant of a refrigeration cycle system and the low-temperature cooling water in a low-temperature cooling water circuit at a chiller. In this device, an aqueous solution of ethylene glycol or the like is used as the low-temperature cooling water.

### SUMMARY

A heat transfer medium is used for a heat transfer system that transfers a cold of a refrigerant circulating through a refrigeration cycle device to an electric device. The heat transfer medium includes water and a lower alcohol that is at least one of methanol or ethanol.

### BRIEF DESCRIPTION OF DRAWINGS

FIG. 1 is a diagram showing a configuration of a heat transfer system according to a first embodiment.

FIG. 2 is a front view showing a second cooler according to the first embodiment.

FIG. 3 is a characteristic diagram showing a relationship between temperature and kinematic viscosity in the first embodiment and a comparative example.

FIG. 4 is a characteristic diagram showing a relationship between a pressure loss of a low-temperature heat transfer medium and a heat transfer coefficient ratio in the second cooler of the first embodiment.

FIG. 5 is an explanatory diagram showing a temperature state inside the second cooler.

FIG. 6 is an explanatory diagram showing freezing points and boiling points of embodiments and comparative examples 1 to 3 in a second embodiment.

FIG. 7 is an explanatory diagram showing freezing points and boiling points of embodiments and comparative examples 1 to 3 in a third embodiment.

FIG. 8 is a characteristic diagram showing a relationship between temperature and kinematic viscosity in an embodiment 1 and a comparative example 1 in a fourth embodiment.

FIG. 9 is a graph showing electrical conductivity in an embodiment 2 and a comparative example 2 in the fourth embodiment.

### DESCRIPTION OF EMBODIMENTS

To begin with, examples of relevant techniques will be described.

A device cools a low-temperature cooling water by exchanging heat between a refrigerant of a refrigeration cycle system and the low-temperature cooling water in a low-temperature cooling water circuit at a chiller. In this device, an aqueous solution of ethylene glycol or the like is used as the low-temperature cooling water.

However, since the aqueous solution of ethylene glycol has a high viscosity at a low temperature, the pressure loss in the low temperature cooling water circuit may increase. Therefore, a pumping power for circulating the low-temperature cooling water has to be increased.

In view of the above points, it is an object of the present disclosure to suppress an increase in viscosity of a heat transfer medium at a low temperature.

In order to achieve the above object, the heat transfer medium according to one aspect of the present disclosure is used for a heat transfer system that transfers a cold of a refrigerant circulating through a refrigeration cycle device to an electric device. The heat transfer medium includes water and a lower alcohol that is at least one of methanol or ethanol.

As described above, by using the heat transfer medium containing water and the lower alcohol that is at least one of methanol and ethanol, it is possible to suppress an increase in viscosity under a low-temperature environment.

Hereinafter, embodiments for implementing the present disclosure will be described referring to drawings. In each embodiment, portions corresponding to those described in the preceding embodiment are denoted by the same reference numerals, and overlapping descriptions may be omitted. In a case where only a part of a configuration is described in each embodiment, the other embodiments described above are capable of being applied for the other parts of the configuration. Not only a combination of parts that clearly indicate that the combination is possible in each embodiment, but also a partial combination of embodiments even if the combination is not specified is also possible when there is no problem in the combination.

### First Embodiment

A first embodiment of the present disclosure will be described below with reference to the drawings. The heat transfer system of the present embodiment is mounted in an electric vehicle that obtains a driving force for traveling the vehicle from a traveling electric motor. Alternatively, the heat transfer system of the present embodiment may be mounted in a hybrid vehicle which obtains a driving force for traveling the vehicle from both an engine (i.e., an internal combustion engine) and a traveling electric motor. The heat transfer system of the present embodiment serves as an air-conditioner for adjusting the temperature in a vehicle interior, and also serves as a temperature adjusting device for adjusting the temperature of a battery 33 or the like mounted in the vehicle.

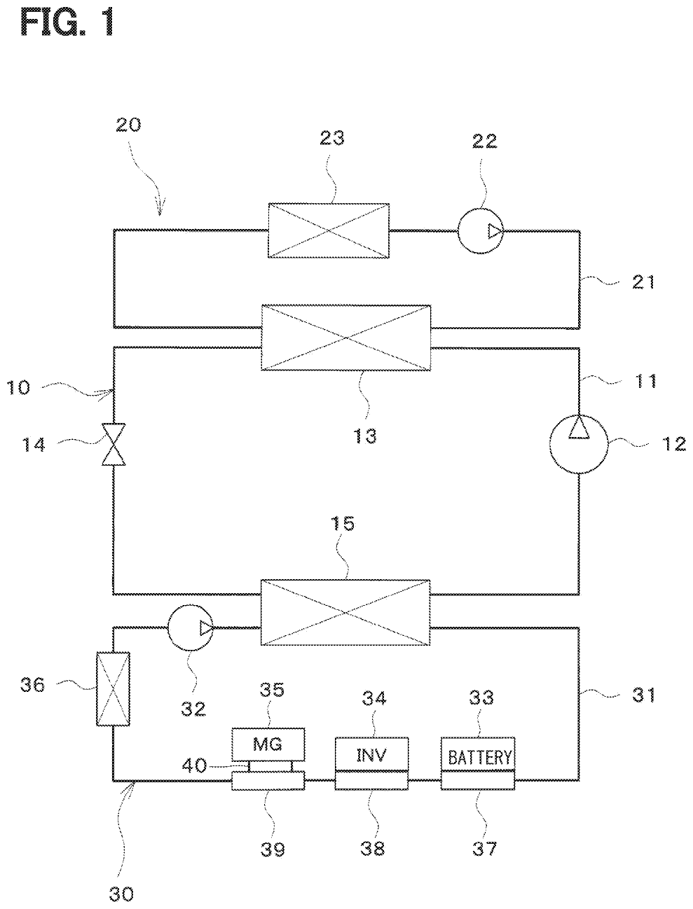

As shown in FIG. 1, the heat transfer system includes a refrigeration cycle device 10, a high-temperature medium circuit 20 that is a high-temperature heat transfer medium circuit, and a low-temperature medium circuit 30 that is a heat transfer medium circuit. In the high-temperature medium circuit 20 and the low-temperature medium circuit 30, heat is transferred through the heat transfer medium. The heat transfer medium in the low-temperature medium circuit 30 has a lower temperature than the heat transfer medium in the high-temperature medium circuit 20. Thereafter, the heat transfer medium in the high-temperature medium circuit 20 may be also referred to as a high-temperature heat transfer medium, and the heat transfer medium in the low-temperature medium circuit 30 is also referred to as a low-temperature heat transfer medium.

The refrigeration cycle device 10 is a vapor compression refrigerator and has a refrigerant circulation passage 11 through which a refrigerant circulates. The refrigeration cycle device 10 serves as a heat pump that pumps heat from the low-temperature heat transfer medium in the low-temperature medium circuit 30 to the refrigerant.

According to the refrigeration cycle device 10 of the present embodiment, a Freon-based refrigerant is adopted as the refrigerant to constitute a subcritical refrigeration cycle in which a high-pressure refrigerant does not exceed a critical pressure of the refrigerant. A compressor 12, a condenser 13 which is a heating heat exchanger, an expansion valve 14, and a heat transfer medium evaporator 15 which is a cooling heat exchanger are arranged in the refrigerant circulation passage 11.

The compressor 12 may be an electric compressor that is driven by power supplied from the battery 33. The compressor 12 is configured to draw, compress, and discharge the refrigerant. The condenser 13 is a high-pressure heat exchanger that condenses a high-pressure refrigerant by exchanging heat between the high-pressure refrigerant discharged from the compressor 12 and the heat transfer medium in the high-temperature medium circuit 20. In the condenser 13, the heat transfer medium in the high-temperature medium circuit 20 is heated by the high-pressure refrigerant in the refrigeration cycle device 10.

The expansion valve 14 serves as a decompressor that is configured to decompress and expand the liquid-phase refrigerant flowing out of the condenser 13. The expansion valve 14 is a thermal expansion valve having a temperature sensor and configured to move a valve element using a mechanical mechanism such as a diaphragm.

The heat transfer medium evaporator 15 is a low-pressure heat exchanger that evaporates the low-pressure refrigerant flowing out of the expansion valve 14 by exchanging heat between the low-pressure refrigerant and the heat transfer medium in the low-temperature medium circuit 30. The vapor-phase refrigerant evaporated in the heat transfer medium evaporator 15 is sucked into the compressor 12 and then is compressed.

The heat transfer medium evaporator 15 is a chiller that cools the heat transfer medium in the low-temperature medium circuit 30 with the low-pressure refrigerant in the refrigeration cycle device 10. In the heat transfer medium evaporator 15, the heat of the heat transfer medium in the low temperature medium circuit 30 is absorbed by the refrigerant of the refrigeration cycle device 10.

The high-temperature medium circuit 20 has a high-temperature circulation passage 21 through which the high-temperature heat transfer medium circulates. Ethylene glycol-based antifreeze solution (LLC) or the like can be used as the high-temperature heat transfer medium. The high-temperature heat transfer medium is enclosed in pipes constituting the high-temperature circulation passage 21. The high-temperature medium circuit 20 of the present embodiment is a closed-type circuit without a pressure adjusting valve that opens when the pressure of the high-temperature heat transfer medium exceeds a predetermined value. That is, the high temperature medium circuit 20 of this embodiment is sealed.

A high-temperature pump 22, a heater core 23, and a condenser 13 are arranged in the high-temperature circulation passage 21.

The high-temperature pump 22 draws and discharges the heat transfer medium circulating through the high-temperature circulation passage 21. The high-temperature pump 22 is an electric pump. The high-temperature pump 22 adjusts a flow rate of the heat transfer medium circulating through the high-temperature medium circuit 20.

The heater core 23 is a heat exchanger for heating air. The heater core 23 is configured to heat air to be supplied into the vehicle interior through heat exchange between the heat transfer medium in the high-temperature medium circuit 20 and the air. In the heater core 23, the air blown into the vehicle interior is heated by the heat transfer medium.

The air heated at the heater core 23 is supplied into the vehicle interior to heat the vehicle interior. Heating by the heater core 23 is mainly performed in winter. In the heat transfer system of the present embodiment, heat of an external air absorbed by the low-temperature heat transfer medium in the low-temperature medium circuit 30 is pumped up by the refrigeration cycle device 10 to the high-temperature heat transfer medium in the high-temperature medium circuit 20 and used for heating the vehicle interior.

The low-temperature medium circuit 30 has a low-temperature circulation passage 31 through which the low-temperature heat transfer medium circulates. The low-temperature heat transfer medium is enclosed in pipes constituting the low-temperature circulation passage 31. The low-temperature medium circuit 30 of the present embodiment is a closed-type circuit without a pressure adjusting valve that opens when the pressure of the low-temperature heat transfer medium exceeds a predetermined value. That is, the low temperature medium circuit 30 of this embodiment is sealed. Details of the low-temperature heat transfer medium will be described later.

A low-temperature pump 32, the heat transfer medium evaporator 15, the battery 33, an inverter 34, a motor generator 35, and an external heat exchanger 36 are arranged in the low-temperature circulation passage 31. In the example shown in FIG. 1, the battery 33, the inverter 34, the motor generator 35, the external heat exchanger 36, and the low-temperature pump 32 are connected to each other in this order in the flow direction of the low-temperature heat transfer medium, but the connecting order is not necessarily limited to this order. Further, in the example shown in FIG. 1, the battery 33, the inverter 34, the motor generator 35, the external heat exchanger 36, and the low-temperature pump 32 are connected to each other in series, but one or more of these devices may be connected to other device in parallel.

The low-temperature pump 32 draws and discharges the heat transfer medium circulating through the low-temperature circulation passage 31. The low-temperature pump 32 is an electric pump. The low-temperature pump 32 adjusts a flow rate of the heat transfer medium circulating through the low-temperature medium circuit 30.

The battery 33 is a rechargeable/dischargeable secondary battery, and for example, a lithium ion battery can be used. As the battery 33, an assembled battery formed of multiple battery cells can be used.

The battery 33 can be charged with power supplied from an external power source (in other words, a commercial power source) when the vehicle is stopped. The power stored in the battery 33 may be supplied to the electric motor for driving the vehicle, and also be supplied to various devices, which are mounted in the vehicle, such as various electric components in the heat transfer system.

The inverter 34 converts DC power supplied from the battery 33 into AC power and outputs it to the motor generator 35. The motor generator 35 is configured to generate a driving force using the electric power output from the inverter 34 and generate regenerative electric power when the vehicle decelerates or travels downhill. The external heat exchanger 36 exchanges heat between the heat transfer medium in the low-temperature medium circuit 30 and the external air. The external heat exchanger 36 receives an external air supplied from an outdoor blower (not shown).

The battery 33, the inverter 34, and the motor generator 35 are electric devices that operate using electricity and generate heat during operation. The battery 33, the inverter 34, and the motor generator 35 are cooling target devices that are cooled by the low-temperature heat transfer medium.

The low-temperature circulation passage 31 of the present embodiment is provided with coolers 37 to 39 that serve for the electric devices 33 to 35, respectively. The first cooler 37 serves for the battery 33, the second cooler 38 serves for the inverter 34, and the third cooler 39 serves for the motor generator 35.

The low-temperature heat transfer medium circulates through the coolers 37 to 39. The electric devices 33 to 35 are cooled by the low-temperature heat transfer medium flowing through the coolers 37 to 39.

In the first cooler 37 and the second cooler 38, the battery 33 and the inverter 34 are directly cooled by the low-temperature heat transfer medium, respectively, without through another heat transfer medium. The third cooler 39 is an oil cooler that cools an oil circulating through an oil circuit 40 by the low-temperature heat transfer medium. The oil flows inside the motor generator 35 to lubricate and cool the motor generator 35.

In the coolers 37 to 39, heat is transferred from the battery 33, the inverter 34, and the motor generator 35, which are cooling target devices, to the low-temperature heat transfer medium. In the external heat exchanger 36, heat is transferred from the external air to the low-temperature heat transfer medium. That is, the battery 33, the inverter 34, the motor generator 35, and the external heat exchanger 36 are heat absorbed devices that give heat to the low-temperature heat transfer medium.

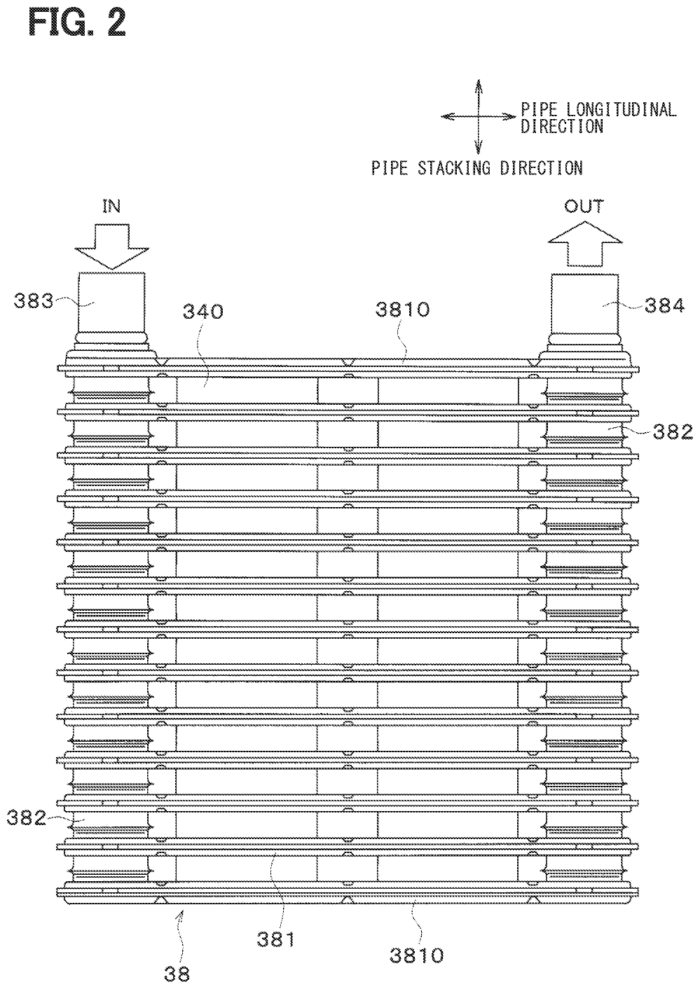

Next, a specific configuration of the second cooler 38 will be described. As shown in FIG. 2, the second cooler 38 of the present embodiment is a stacked heat exchanger that cools both sides of multiple electronic components 340 constituting the inverter 34.

Each of the electronic components 340 of the present embodiment has a double-sided heat dissipation structure in which heat is dissipated from both sides of the electronic components 340. As the electronic components 340, a semiconductor module incorporating a semiconductor element such as an IGBT and a diode can be used.

The second cooler 38 includes passage pipes 381 and communication portions 382. Each of the passage pipes 381 is formed in a flat shape and constitutes a low-temperature heat transfer medium passage through which the low-temperature heat transfer medium in the low-temperature medium circuit 30 flows. The passage pipes 381 are stacked with each other so that the electronic components 340 can be sandwiched by the passage pipes 381.

The communication portions 382 fluidly connect between the multiple passage pipes 381. The communication portions 382 are connected to both ends of the passage pipes 381 in a longitudinal direction of the passage pipes 381.

In the present embodiment, each of the passage pipes 381 has two flat surfaces and two electronic components 340 are provided for each of the two flat surfaces. The two electronic components 340 provided on the flat surface of the passage pipe 381 are arranged in series in the flow direction of the low-temperature heat transfer medium.

Here, among the multiple passage pipes 381, the passage pipes 381 arranged on outermost sides of the passage pipes 381 in a stacking direction is referred to as outer passage pipes 3810. One of the two outer passage pipes 3810 of the second cooler 38 defines an inlet 383 and an outlet 384 in both ends of the one of the two outer passage pipes 3810 in the longitudinal direction.

The inlet 383 is an introducing portion that introduces the low-temperature heat transfer medium into the second cooler 38. The outlet 384 is a discharge portion that discharges the low-temperature heat transfer medium from the second cooler 38. The inlet 383 and the outlet 384 are joined to the one of the two outer passage pipes 3810 by brazing. The passage pipes 381, the communication portions 382, the inlet 383, and the outlet 384 of the present embodiment are each made of aluminum.

The low-temperature heat transfer medium is introduced into one of the communication portions 382 through the inlet 383 and flows through each of the passage pipes 381 from one ends in the longitudinal direction of the passage pipes 381 to the other ends. Then, the low-temperature heat transfer medium flows into the other of the communication portions 382 and is discharged out through the outlet 384. In this way, while the low-temperature heat transfer medium flows through the passage pipes 381, heat exchange is performed between the low-temperature heat transfer medium and the electronic components 340, so that the electronic components 340 are cooled.

Next, the low-temperature heat medium will be described. It is preferable that the low-temperature heat transfer medium have low viscosity at a low temperature and high cooling capacity.

In this embodiment, an aqueous methanol solution containing methanol and water is used as the low-temperature heat transfer medium. In the present embodiment, the amount of water in the low-temperature heat transfer medium is equal to or greater than the amount of methanol. That is, the proportion of water in the aqueous methanol solution is 50% or more.

Specifically, a weight ratio of methanol to water in the low-temperature heat transfer medium is set such as methanol:water=35:65 to 50:50. That is, the weight ratio of methanol to water in the low temperature heat transfer medium is within the range of 35:65 or more and 50:50 or less.

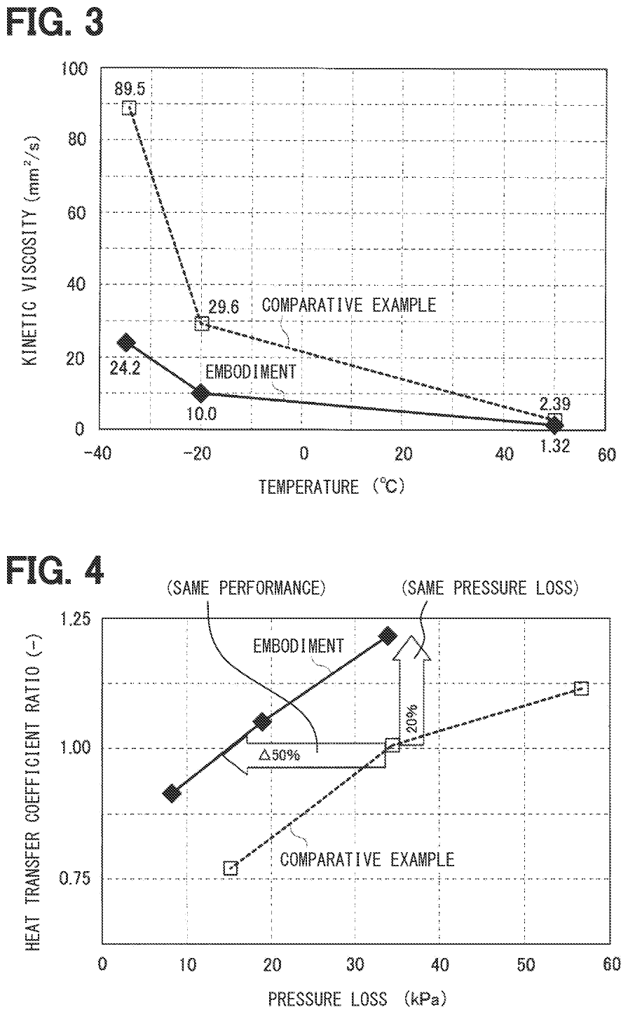

Here, FIG. 3 shows a relationship between temperature and kinematic viscosity in an aqueous methanol solution (methanol:water=35:65 to 50:50) as an embodiment and an ethylene glycol-based antifreeze solution (LLC) as a comparative example.

As shown by the solid line in FIG. 3, the aqueous methanol solution as the embodiment has a kinematic viscosity of 10.0 mm²/s at −20° C. and a kinematic viscosity of 24.2 mm²/s at −35° C. As shown by the broken line in FIG. 3, the ethylene glycol antifreeze solution as the comparative example has a kinematic viscosity of 29.6 mm²/s at −20° C. and a kinematic viscosity of 89.5 mm²/s at −35° C. As described above, the aqueous methanol solution can secure a low viscosity at a low temperature.

Here, FIG. 4 shows a relationship between a pressure loss and a heat transfer coefficient ratio of the low-temperature heat transfer medium in the second cooler 38 when the temperature of the low-temperature heat transfer medium is 25° C. The heat transfer coefficient ratio shown on the vertical axis of FIG. 4 is expressed compared to a heat transfer coefficient of the ethylene glycol-based antifreeze solution. The heat transfer coefficient when the ethylene glycol-based antifreeze solution is used as the low-temperature heat transfer medium and when the pressure loss of the low-temperature heat transfer medium in the second cooler 38 is 35 kPa is set to 1.0.

In FIG. 4, a relationship between the pressure loss and the heat transfer coefficient ratio when the aqueous methanol solution of the embodiment is used as the low-temperature heat transfer medium is shown by the solid line. Further, in FIG. 4, the relationship between the pressure loss and the heat transfer coefficient ratio when the ethylene glycol-based antifreeze solution of the comparative example is used as the low-temperature heat transfer medium is shown by the broken line.

As shown in FIG. 4, under the condition that the temperature of the low-temperature heat transfer medium is 25° C., a pressure loss can be reduced by 50% at the same performance (i.e., the same heat transfer coefficient ratio) when the aqueous methanol solution is used as the low-temperature heat transfer medium compared to when the ethylene glycol-based antifreeze is used as the low-temperature heat transfer medium.

Here, as shown in FIG. 3, at 25° C., the kinematic viscosity of the aqueous methanol solution is about one second of the kinematic viscosity of the ethylene glycol-based antifreeze solution. On the other hand, at −35° C., the kinematic viscosity of the aqueous methanol solution is about one fourth of the kinematic viscosity of the ethylene glycol-based antifreeze solution.

Therefore, under condition at −35° C., the pressure loss can be significantly reduced by more than 50% when the aqueous methanol solution is used as the low-temperature heat transfer medium compared to when the ethylene glycol-based antifreeze solution is used as the low-temperature heat transfer medium. As described above, when the aqueous methanol solution is used as the low-temperature heat transfer medium, the pressure loss at a low temperature can be maintained at a low level.

Further, as shown in FIG. 4, under the condition that the temperature of the low-temperature heat transfer medium is 25° C., the heat transfer coefficient ratio can be increased by 20% at the same pressure loss when the aqueous methanol solution is used as the low-temperature heat transfer medium compared to when the ethylene glycol-based antifreeze solution is used as the low-temperature heat transfer medium. As described above, when the aqueous methanol solution is used as the low temperature heat transfer medium, the heat transfer coefficient of the low-temperature heat transfer medium can be improved and the cooling performance of the coolers 37 to 39 can be improved.

The low-temperature heat transfer medium of the present embodiment contains a rust inhibitor in addition to water and methanol. The rust inhibitor is used for preventing corrosion of the pipes through which the low-temperature heat transfer medium flows. The concentration of the rust inhibitor in the low-temperature heat transfer medium can be appropriately set, and may be several percent.

Examples of the rust inhibitor include aliphatic monocarboxylic acids, aromatic monocarboxylic acids, aromatic dicarboxylic acids or salts thereof, borates, silicates, silicic acids, phosphates, phosphoric acid, nitrites, and nitrates, molybdate, triazole, and thiazole.

As described above, in the present embodiment, an aqueous methanol solution containing methanol and water is used as the low-temperature heat transfer medium. As a result, it is possible to suppress an increase in viscosity under a low temperature environment as compared with an ethylene glycol-based antifreeze solution. Therefore, even under a low-temperature environment, an increase in pressure loss in the low-temperature medium circuit 30 can be suppressed, and an increase in power of the low-temperature pump 32 can be suppressed.

Further, the external heat exchanger 36 can be easily downsized by narrowing passages for the low-temperature heat transfer medium, and the degree of freedom in design can be improved. Further, since the flow rate of the low-temperature heat transfer medium passing through the external heat exchanger 36 is increased, frost formation on the external heat exchanger 36 can be suppressed.

Further, since the increase in viscosity of the low-temperature heat transfer medium under a low-temperature environment can be suppressed, the flow rate of the low-temperature heat transfer medium can be increased as compared to the ethylene glycol-based antifreeze solution. As a result, the flow rate of the low-temperature heat transfer medium can be increased, and the heat transfer efficiency of the low-temperature heat transfer medium can be further improved. Further, by improving the heat transfer coefficient of the low-temperature heat transfer medium, it is possible to improve the heat transfer coefficient of the entire system including the external heat exchanger 36.

Further, in the present embodiment, the amount of water contained in the low-temperature heat transfer medium is equal to or greater than the amount of methanol. The aqueous methanol solution can maintain a higher proportion of water while having a low freezing point as compared to an ethylene glycol-based antifreeze solution. Therefore, by increasing the proportion of water that has a large heat capacity in the aqueous methanol solution, the heat capacity of the low-temperature heat transfer medium can be increased, and the thermal conductivity can be further increased.

Further, by increasing the proportion of water in the aqueous methanol solution, the viscosity of the low-temperature heat transfer medium can be further lowered. Further, by increasing the proportion of water in the aqueous methanol solution, the cost of the low-temperature heat transfer medium can be reduced.

By the way, when the pipes through which the low-temperature heat transfer medium flows is made of aluminum, there is a possibility that methanol contained in the low-temperature heat transfer medium chemically reacts with aluminum constituting the pipes to generate aluminum alkoxide. As a result, the amount of methanol contained in the low-temperature heat transfer medium may be reduced, and the effect of suppressing the increase in viscosity under a low-temperature environment may be reduced. That is, a freezing point may be rise.

On the other hand, as in the present embodiment, the amount of water contained in the low-temperature heat transfer medium is equal to or greater than the amount of methanol, and the proportion of water contained in the low-temperature heat transfer medium is high, so that the formation of aluminum alkoxide can be suppressed. As a result, even if the pipes through which the low-temperature heat transfer medium flows are made of aluminum, it is possible to reliably suppress the increase in viscosity under a low-temperature environment. That is, the freezing point can be restricted from rising.

Further, by setting the weight ratio of methanol to water in the low-temperature heat transfer medium to a value within 35:65 to 50:50, the freezing point of the low-temperature heat transfer medium can be set to −35° C. or lower. Therefore, it is possible to restrict the low-temperature heat transfer medium from freezing in a low temperature environment such as winter.

Further, by adding the rust inhibitor into the low-temperature heat transfer medium, it is possible to suppress the corrosion of the pipes through which the low-temperature heat transfer medium flows. Thereby, a durability of the heat transfer system can be improved.

### Second Embodiment

A second embodiment of the present disclosure will be described below with reference to the drawings. It is preferable that a low-temperature heat transfer medium of the second embodiment have a low viscosity at a low temperature and a high boiling point.

In this embodiment, an aqueous methanol solution containing methanol, water, and a boiling point elevation agent is used as the low-temperature heat transfer medium. In the present embodiment, the proportion of the boiling point elevation agent in the aqueous methanol solution is less than 50%.

As the boiling point elevation agent, a substance having solubility in both water and methanol and having a boiling point higher than that of a mixture of water and methanol can be used. Specifically, at least one of alcohol, amine, ether, and carboxylic acid can be used as the boiling point elevation agent.

As alcohol, at least one of an alcohol having one hydroxyl group and three or more carbon atoms and an alcohol having two or more hydroxyl groups and two or more carbon atoms can be used. As the alcohol having two or more hydroxyl groups and two or more carbon atoms, for example, at least one of ethylene glycol, diethylene glycol, triethylene glycol, and tetraethylene glycol can be used.

As amine, at least one of formamide and methylamine can be used. As ether, at least any one of dimethyl ether, ethyl methyl ether, diethyl ether and glycol ether can be used. As carboxylic acid, at least one of formic acid and acetic acid can be used.

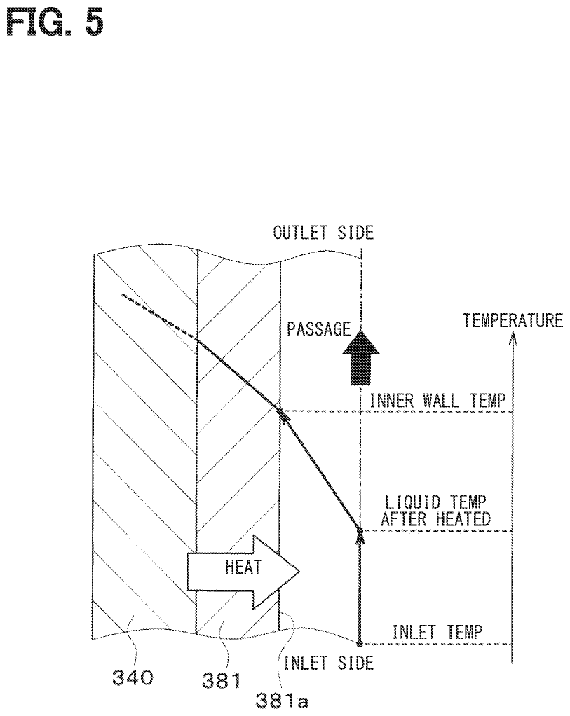

As shown in FIG. 5, the heat generated in the electronic components 340 of the inverter 34 is transferred to the low-temperature heat transfer medium flowing through the passage pipes 381 through inner wall surfaces 381a of the passage pipes 381. As a result, the temperature of the low-temperature heat transfer medium flowing through the passage pipes 381 rises.

At this time, the temperature of a portion of the low-temperature heat transfer medium passage in the passage pipes 381 facing the inner wall surface 381a becomes higher than the temperature of the other portions. That is, the temperature of the portion facing the inner wall surfaces 381a is highest among the low-temperature heat transfer medium passages in the passage pipes 381. Therefore, the temperature of the inner wall surfaces 381a of the passage pipes 381 is substantially the maximum temperature of the low-temperature heat transfer medium. Therefore, by increasing the boiling point of the low-temperature heat transfer medium to exceed the temperature of the inner wall surfaces 381a of the passage pipes 381, it is possible to prevent the low-temperature heat transfer medium from boiling in the passage pipes 381.

In particular, in a high temperature environment such as summer, the temperature of the inverter 34 tends to rise, and the temperature of the inner wall surfaces 381a of the passage pipes 381 in the second cooler 38 rises. Therefore, it is preferable that the boiling point of the low-temperature heat transfer medium be equal to or higher than the temperature of the inner wall surfaces 381a of the passage pipes 381 (e.g., about 90° C. in this embodiment) in summer. Further, the freezing point of the low-temperature heat transfer medium be preferably equal to or lower than −35° C. to prevent the low-temperature heat transfer medium from freezing in a low temperature environment such as winter.

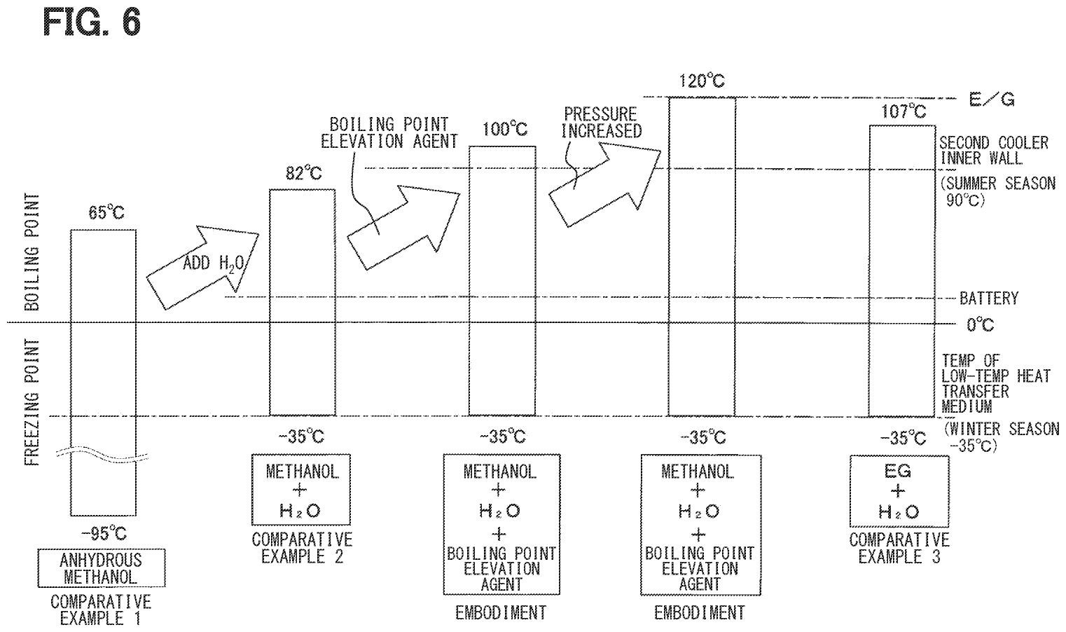

As shown in FIG. 6, anhydrous methanol as a comparative example 1 has a freezing point of −95° C. and a boiling point of 65° C. An aqueous methanol solution as a comparative example 2 that contains methanol and water (methanol:water=35:65) has a freezing point of −35° C. and a boiling point of 82° C.

On the other hand, an aqueous methanol solution as an embodiment that contains methanol, water, and a boiling point elevation agent (methanol:water:boiling point elevation agent=10:50:40) has a freezing point of −35° C. and a boiling point of 100° C. As described above, the aqueous methanol solution containing methanol, water, and the boiling point elevation agent can secure a high boiling point and a low freezing point. Then, when the aqueous methanol solution of the embodiment that contains methanol, water, and the boiling point elevation agent is sealed into the low-temperature medium circuit 30 at high pressure, the boiling point of the aqueous methanol solution can be further increased.

The ethylene glycol-based antifreeze solution (ethylene glycol:water=50:50) as a comparative example 3 has a freezing point of −35° C. and a boiling point of 107° C. However, since the kinematic viscosity of the ethylene glycol-based antifreeze solution at −35° C. is higher than that of the aqueous methanol solution, it is not possible to secure a low viscosity at a low temperature.

The low-temperature heat transfer medium of the present embodiment contains a rust inhibitor in addition to water, methanol, and the boiling point elevation agent. The concentration of the rust inhibitor in the low-temperature heat transfer medium can be appropriately set, and may be several percent. As the rust inhibitor, the same one as in the first embodiment can be used.

As described above, in the present embodiment, an aqueous methanol solution containing methanol, water, and a boiling point elevation agent is used as the low-temperature heat transfer medium. As a result, it is possible to suppress an increase in viscosity in a low temperature environment as compared with an ethylene glycol-based antifreeze solution. Therefore, it is possible to obtain the same effect as those of the first embodiment.

Further, by adding the boiling point elevation agent into the low-temperature heat transfer medium, the boiling point of the low-temperature heat transfer medium can be increased. According to this, even if the low-temperature heat transfer medium is heated by a heat load, it is possible to restrict the low-temperature heat transfer medium in the low-temperature medium circuit 30 from boiling. Therefore, it is possible to suppress the occurrence of dryout which is a state where the liquid low-temperature heat transfer medium does not exist in a part of the low-temperature medium circuit 30. As a result, in the heat transfer medium evaporator 15, heat exchange between the low-pressure refrigerant and the low-temperature heat transfer medium can be stably performed.

Further, in the present embodiment, the low-temperature medium circuit 30 is a closed type. According to this, the low-temperature heat transfer medium can be sealed into the low-temperature heat transfer medium at high pressure, so that the boiling point of the low-temperature heat transfer medium can be further increased.

Further, in the present embodiment, the rust inhibitor is added into the low-temperature heat transfer medium. According to this, since the corrosion of the pipes through which the low-temperature heat transfer medium flows can be suppressed, the durability of the heat transfer system can be improved. Further, the boiling point of the low-temperature heat transfer medium can be increased due to the boiling point elevation effect.

### Third Embodiment

A third embodiment of the present disclosure will be described below with reference to the drawings. It is preferable that the low-temperature heat transfer medium of the third embodiment has a low viscosity at a low temperature and a high boiling point.

In this embodiment, an aqueous ethanol solution containing ethanol and water is used as the low-temperature heat transfer medium. In the present embodiment, the amount of water in the low-temperature heat transfer medium is equal to or greater than the amount of ethanol. That is, the proportion of water in the aqueous ethanol solution is 50% or more.

Specifically, a weight ratio of ethanol to water in the low-temperature heat transfer medium is set to a value within a range ethanol:water=35:65 to 50:50. That is, the weight ratio of ethanol to water in the low-temperature heat transfer medium is within the range of 35:65 or more and 50:50 or less. Further, it is preferable that the weight ratio of ethanol to water in the low-temperature heat transfer medium be ethanol:water=43:57 to 50:50.

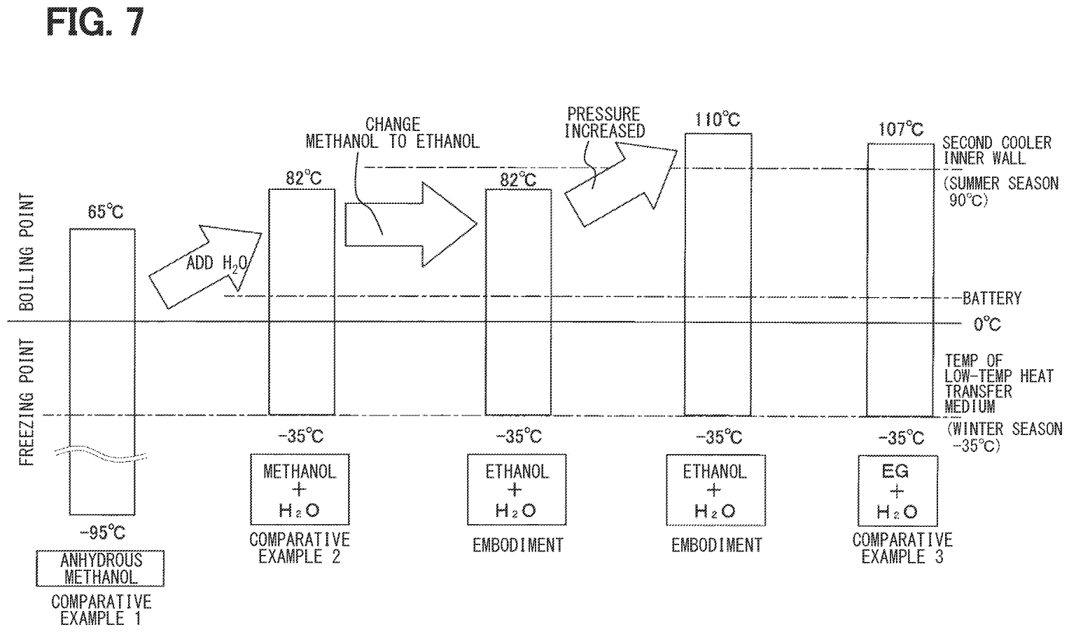

As shown in FIG. 7, anhydrous methanol as a comparative example 1 has a freezing point of −95° C. and a boiling point of 65° C. An aqueous methanol solution as a comparative example 2 that contains methanol and water (methanol:water=35:65) has a freezing point of −35° C. and a boiling point of 82° C.

On the other hand, the aqueous ethanol solution as an embodiment that contains ethanol and water (ethanol:water=45:55) has the freezing point of −35° C. and the boiling point of 82° C. As described above, the aqueous ethanol solution can secure a high boiling point equivalent to that of the comparative example 2 and a low freezing point.

In addition, according to this embodiment, since ethanol is used as a freezing point depression agent, the safety is higher than that of the comparative example 2. Therefore, as compared with the comparative example 2, the handling of the cooling water can be easier in the scene of transporting and replenishing the cooling water. In addition, when the aqueous ethanol solution is sealed into the low-temperature medium circuit 30 at high pressure, the boiling point of the aqueous ethanol solution can be further increased.

The ethylene glycol-based antifreeze solution (ethylene glycol:water=50:50) as a comparative example 3 has a freezing point of −35° C. and a boiling point of 107° C. However, since the kinematic viscosity of the ethylene glycol-based antifreeze solution at −35° C. is higher than that of the aqueous ethanol solution, it is not possible to secure a low viscosity at a low temperature.

The low-temperature heat transfer medium of the present embodiment contains a rust inhibitor in addition to water and ethanol. The concentration of the rust inhibitor in the low-temperature heat transfer medium can be appropriately set, and may be several percent. As the rust inhibitor, the same one as in the first embodiment can be used.

As described above, in the present embodiment, an aqueous ethanol solution containing ethanol and water is used as the low-temperature heat transfer medium. As a result, it is possible to suppress an increase in viscosity in a low temperature environment as compared with an ethylene glycol-based antifreeze solution. Therefore, it is possible to obtain the same effect as those of the first embodiment.

Further, by using an aqueous ethanol solution as the low-temperature heat transfer medium, the boiling point of the low-temperature heat transfer medium can be increased. Specifically, the boiling point of the low-temperature heat transfer medium can be equal to or higher than the temperature of the inner wall surfaces 381a of the passage pipes 381 in summer.

According to this, even if the low-temperature heat transfer medium is heated by the heat load, the low-temperature heat transfer medium is restricted from boiling in the low-temperature medium circuit 30 (specifically, in the passage pipes 381 of the second cooler 38). Therefore, it is possible to suppress the occurrence of dryout which is a state where the liquid low-temperature heat transfer medium does not exist in a part of the low-temperature medium circuit 30. As a result, in the heat transfer medium evaporator 15, heat exchange between the low-pressure refrigerant and the low-temperature heat transfer medium can be stably performed.

Further, in the present embodiment, the amount of water contained in the low-temperature heat transfer medium is equal to or greater than the amount of ethanol. The aqueous ethanol solution can maintain a higher proportion of water while having a low freezing point as compared to an ethylene glycol-based antifreeze solution. Therefore, by increasing the proportion of water having a large heat capacity in the aqueous ethanol solution, the heat capacity of the low-temperature heat transfer medium can be increased, and the thermal conductivity can be further increased.

Further, by increasing the proportion of water in the aqueous ethanol solution, the viscosity of the low-temperature heat transfer medium can be further lowered. Further, by increasing the proportion of water in the aqueous ethanol solution, the cost of the low-temperature heat transfer medium can be reduced.

By the way, when the pipes through which the low-temperature heat transfer medium flows is made of aluminum, there is a possibility that ethanol contained in the low-temperature heat transfer medium chemically reacts with aluminum constituting the pipes to generate aluminum alkoxide. As a result, the amount of ethanol contained in the low-temperature heat transfer medium may be reduced, and the effect of suppressing the increase in viscosity in a low-temperature environment may be reduced. That is, a freezing point may be rise.

On the other hand, as in the present embodiment, the amount of water contained in the low-temperature heat transfer medium is equal to or greater than the amount of ethanol and the proportion of water contained in the low-temperature heat transfer medium is high, thereby suppressing the formation of aluminum alkoxide. As a result, even if the pipes through which the low-temperature heat transfer medium flows is made of aluminum, it is possible to reliably suppress the increase in viscosity in a low-temperature environment. That is, the freezing point can be restricted from rising.

Further, by setting the weight ratio of ethanol to water in the low-temperature heat transfer medium to a value within a range of 43:57 to 50:50, the freezing point of the low-temperature heat transfer medium can be set to −35° C. Therefore, it is possible to restrict the low-temperature heat transfer medium from freezing in a low temperature environment such as winter.

Further, in the present embodiment, the rust inhibitor is added into the low-temperature heat transfer medium. According to this, since the corrosion of the pipes through which the low-temperature heat transfer medium flows can be suppressed and the durability of the heat transfer system can be improved. Further, the boiling point of the low-temperature heat transfer medium can be increased due to the boiling point elevation effect.

Further, in the present embodiment, the low-temperature medium circuit 30 is a closed type. According to this, the low-temperature heat transfer medium can be sealed into the low-temperature heat transfer medium at high pressure, so that the boiling point of the low-temperature heat transfer medium can be further increased.

### Fourth Embodiment

A fourth embodiment of the present disclosure will be described below with reference to the drawings. It is preferable that a low-temperature heat transfer medium of the fourth embodiment have low viscosity at low temperature and a low conductivity.

The low-temperature heat transfer medium of the present embodiment contains a lower alcohol which is at least one of methanol and ethanol, water, and a nonionic rust inhibitor. Hereinafter, in the present specification, at least one of methanol and ethanol is also referred to as a lower alcohol.

Here, methanol has a melting point of −97° C. and a boiling point of 64.5° C. Ethanol has a melting point of −114° C. and a boiling point of 78.3° C. As the lower alcohol, an alcohol having appropriate properties may be appropriately selected from methanol and ethanol according to the usage environment and the like.

In the present embodiment, the amount of water in the low-temperature heat transfer medium is equal to or higher than the amount of lower alcohol. That is, the proportion of water in the low-temperature heat transfer medium is 50% or more.

Specifically, the weight ratio of the lower alcohol to water in the low-temperature heat transfer medium is set to a value within a range lower alcohol:water=35:65 to 50:50. That is, the weight ratio of the lower alcohol to water in the low-temperature heat transfer medium is within the range of 35:65 or more and 50:50 or less.

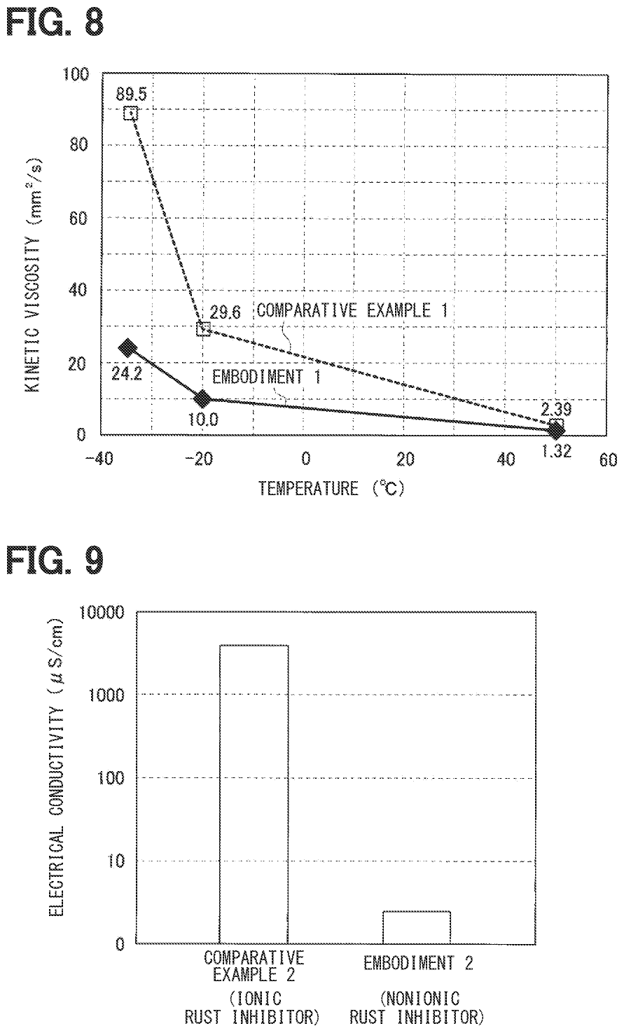

Here, FIG. 8 shows a relationship between temperature and kinematic viscosity in the aqueous methanol solution (methanol:water=35:65 to 50:50) as an embodiment 1 and the ethylene glycol-based antifreeze solution (LLC) as a comparative example 1.

As shown by the solid line in FIG. 8, the aqueous methanol solution as the embodiment 1 has a kinematic viscosity of 10.0 mm²/s at −20° C. and a kinematic viscosity of 24.2 mm²/s at −35° C. As shown by the broken line in FIG. 8, the ethylene glycol-based antifreeze solution as the comparative example 1 has a kinematic viscosity of 29.6 mm²/s at −20° C. and a kinematic viscosity of 89.5 mm²/s at −35° C. As described above, the aqueous methanol solution can secure a low viscosity at a low temperature. Similarly, even with the aqueous ethanol solution, low viscosity at a low temperature can be secured.

The non-ionic rust inhibitor contained in the low-temperature heat transfer medium is used for preventing corrosion of the pipes through which the low-temperature heat transfer medium flows. The concentration of the nonionic rust inhibitor in the low-temperature heat transfer medium can be appropriately set, and may be several percent. Furthermore, since the nonionic rust inhibitor does not exhibit ionic properties even if the nonionic rust inhibitor is dissolved in water, it is possible to suppress an increase in the conductivity of the low-temperature heat transfer medium.

As the nonionic rust inhibitor, silyl ether and/or a triazole-based rust inhibitor can be used. By using silyl ether as the nonionic rust inhibitor, a film can be formed on a surface of aluminum. By using triazole-based compound as the nonionic rust inhibitor, a film can be formed on a surface of copper.

As the silyl ether, those represented by the following general formula (1) can be used

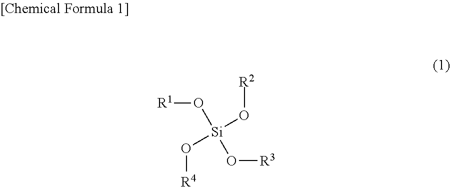

In the general formula (1), R1 to R4 each independently represents a substituent. It is preferable that R1 to R4 be water-insoluble substituents. According to this, the film formed of silyl ether can have water-repellent property, so that the adsorption of water on the surfaces of the aluminum pipes can be inhibited. Therefore, corrosion of the pipes can be effectively suppressed. In the general formula (1), as R1 to R4, for example, a hydrocarbon group or a halogenated hydrocarbon group in which the hydrogen atom of the hydrocarbon group is replaced by a halogen atom can be adopted.

FIG. 9 is a graph showing electrical conductivity of the low-temperature heat transfer medium of an embodiment 2 and a comparative example 2. In the embodiment 2, the nonionic rust inhibitor of the present embodiment (that is, silyl ether and/or triazole-based rust inhibitor) is used as the rust inhibitor. In the comparative example 2, sebacic acid, which is an ionic rust inhibitor, is used as the rust inhibitor.

As shown in FIG. 9, when the nonionic rust inhibitor is used as the rust inhibitor, lower electrical conductivity is obtained than when the ionic rust inhibitor is used as the rust inhibitor.

As described above, in the present embodiment, water, a non-ionic rust inhibitor, and a lower alcohol aqueous solution containing at least one of methanol and ethanol are used as the low-temperature heat transfer medium. As a result, it is possible to suppress an increase in viscosity in a low temperature environment as compared with an ethylene glycol-based antifreeze solution. Therefore, it is possible to obtain the same effect as those of the first embodiment.

Further, in the present embodiment, the low-temperature heat transfer medium contains the non-ionic rust inhibitor. By adding the rust inhibitor into the low-temperature heat transfer medium, corrosion of the pipes through which the low-temperature heat transfer medium flows can be suppressed. Thereby, a durability of the heat transfer system can be improved.

Further, by using the non-ionic rust inhibitor as the rust inhibitor, it is possible to secure low conductivity of the heat transfer medium as compared with the case where the ionic rust inhibitor is used as the rust inhibitor. As a result, it is not necessary to take a large-scale insulation measure for the heat transfer system.

Further, in the present embodiment, the amount of water contained in the low-temperature heat transfer medium is equal to or greater than the amount of the lower alcohol. The aqueous methanol solution and the aqueous ethanol solution can maintain a higher proportion of water while having a low freezing point as compared to an ethylene glycol-based antifreeze solution. Therefore, by increasing the proportion of water having a large heat capacity in the low-temperature heat transfer medium, the heat capacity of the low-temperature heat transfer medium can be increased, and the thermal conductivity can be further improved.

Further, by increasing the proportion of water in the low-temperature heat transfer medium, the viscosity of the low-temperature heat transfer medium can be further lowered. Further, by increasing the proportion of water in the low-temperature heat transfer medium, the cost of the low-temperature heat transfer medium can be reduced.

By the way, when the pipes through which the low-temperature heat transfer medium flows is made of aluminum, methanol or ethanol contained in the low-temperature heat transfer medium may chemically reacts with the aluminum constituting the pipes to generate aluminum alkoxide. As a result, the amount of lower alcohol contained in the low-temperature heat transfer medium may be reduced, and the effect of suppressing the increase in viscosity in a low-temperature environment may be reduced. That is, a freezing point may be rise.

On the other hand, as in the present embodiment, the amount of water contained in the low-temperature heat transfer medium is equal to or higher than the amount of the lower alcohol, and the proportion of water contained in the low-temperature heat transfer medium is high to suppress the formation of aluminum alkoxide. As a result, even if the pipes through which the low-temperature heat transfer medium flows is made of aluminum, it is possible to reliably suppress the increase in viscosity in a low-temperature environment. That is, the freezing point can be restricted from rising.

Further, by setting the weight ratio of the lower alcohol to water in the low-temperature heat transfer medium to a value within a range of 35:65 to 50:50, the freezing point of the low-temperature heat transfer medium can be lower than the minimum temperature in the usage environment. Therefore, it is possible to restrict the low-temperature heat transfer medium from freezing in a low temperature environment such as winter.

The present disclosure is not limited to the above embodiments, and can be variously modified, for example, as described below, without departing from the gist of the present disclosure.

For example, in the first embodiment, the aqueous methanol solution is used as the low-temperature heat transfer medium of the low temperature medium circuit 30, but the present disclosure is not limited to this. The aqueous methanol solution may be used as the high-temperature heat transfer medium of the high temperature medium circuit 20. In this case, the heat transfer medium can be shared between the high-temperature medium circuit 20 and the low-temperature medium circuit 30.

Further, in the second embodiment, the aqueous methanol solution containing methanol, water, and a boiling point elevation agent is used as the low-temperature heat transfer medium of the low-temperature medium circuit 30, but the present disclosure is not limited to this. The aqueous methanol solution may be used as the high-temperature heat transfer medium of the high-temperature medium circuit 20. In this case, the heat transfer medium can be shared between the high-temperature medium circuit 20 and the low-temperature medium circuit 30.

Further, in the third embodiment, the aqueous ethanol solution containing ethanol and water is used as the low-temperature heat transfer medium of the low temperature medium circuit 30, but the present disclosure is not limited to this. The aqueous ethanol solution may be used as the high-temperature heat transfer medium of the high-temperature medium circuit 20. In this case, the heat transfer medium can be shared between the high-temperature medium circuit 20 and the low-temperature medium circuit 30.

Further, in the fourth embodiment, an aqueous solution of a lower alcohol containing a lower alcohol, water, and a nonionic rust inhibitor is used as the low-temperature heat transfer medium of the low-temperature medium circuit 30, but the present disclosure is not limited to this. The aqueous solution of the lower alcohol may be used as the high-temperature heat transfer medium of the high-temperature medium circuit 20. In this case, the heat transfer medium can be shared between the high-temperature medium circuit 20 and the low-temperature medium circuit 30.

Further, in each of the above embodiments, an example in which the third cooler 39 is the oil cooler for cooling the oil circulating through the oil circuit 40 with the low-temperature heat transfer medium has been described, but the present disclosure is not limited to this embodiment. For example, the third cooler 39 may be configured to directly cool the motor generator 35 with the low-temperature heat transfer medium without using another heat transfer medium (for example, oil).

Although the present disclosure has been described in accordance with the embodiments, it is understood that the present disclosure is not limited to such embodiments or structures. The present disclosure encompasses various modifications and variations within the scope of equivalents. In addition, various combinations and configurations, as well as other combinations and configurations that include only one element, more, or less, are within the scope and spirit of the present disclosure.

### Outline of Embodiments of the Present Disclosure

A heat transfer medium according to a first aspect of the present disclosure is used for a heat transfer system configured to transfer a cold of a refrigerant circulating through a refrigeration cycle device to an electric device. The heat transfer medium includes water and a lower alcohol which is at least one of methanol and ethanol.

A heat transfer system according to a second aspect of the present disclosure includes a refrigeration cycle device through which a refrigerant circulates, a heat transfer medium circuit through which a heat transfer medium circulates, a cooling heat exchanger configured to cool the heat transfer medium through heat exchange between the refrigerant and the heat transfer medium, and an electric device disposed in the heat transfer heat medium circuit. A heat of the electric device is absorbed by the heat transfer medium. The heat transfer medium includes methanol and water.

According to the second aspect, by using an aqueous methanol solution containing methanol and water as the heat transfer medium, it is possible to suppress an increase in viscosity in a low temperature environment.

A heat transfer system according to a third aspect of the present disclosure includes a refrigeration cycle device through which a refrigerant circulates, a heat transfer medium circuit through which a heat transfer medium circulates, a cooling heat exchanger configured to cool the heat transfer medium through heat exchange between the refrigerant and the heat transfer medium, and an electric device disposed in the heat transfer medium circuit. A heat of the electric device is absorbed by the heat transfer medium. The heat transfer medium includes methanol, water, and boiling point elevation agent.

According to the third aspect, by using an aqueous methanol solution containing methanol, water, and the boiling point elevation agent as the heat transfer medium, it is possible to suppress an increase in viscosity in a low temperature environment, and further suppress boiling of the heat transfer medium.

A heat transfer system according to a fourth aspect of the present disclosure includes a refrigeration cycle device through which a refrigerant circulates, a heat transfer medium circuit through which a heat transfer medium circulates, a cooling heat exchanger configured to cool the heat transfer medium through heat exchange between the refrigerant and the heat transfer medium, and an electric device disposed in the heat transfer medium circuit. A heat of the electric device is absorbed by the heat transfer medium. The heat transfer medium includes ethanol and water.

According to the fourth aspect, by using an aqueous ethanol solution containing ethanol and water as the heat transfer medium, it is possible to suppress an increase in viscosity in a low temperature environment, and further suppress boiling of the heat transfer medium.

A heat transfer system according to a fifth aspect of the present disclosure includes a refrigeration cycle device through which a refrigerant circulates, a heat transfer medium circuit through which a heat transfer medium circulates, a cooling heat exchanger configured to cool the heat transfer medium through heat exchange between the refrigerant and the heat transfer medium, and an electric device disposed in the heat transfer medium circuit. A heat of the electric device is absorbed by the heat transfer medium. The heat transfer medium includes water, a non-ionic rust inhibitor, and a lower alcohol that is at least one of methanol and ethanol.

According to the fifth aspect, by using the aqueous solution of the lower alcohol containing water and the lower alcohol that is at least one of methanol and ethanol and water as the heat transfer medium, it is possible to suppress an increase in viscosity in a low temperature environment. Further, by using the non-ionic rust inhibitor as the rust inhibitor, low conductivity of the heat transfer medium can be secured.

What is claimed is:

1. A heat transfer medium used for a heat transfer system configured to transfer a cold of a refrigerant circulating through a refrigeration cycle device to an electric device, the heat transfer medium comprising:
a lower alcohol that is at least one of methanol or ethanol; and
water.

2. The heat transfer medium according to claim 1, wherein
the lower alcohol is the methanol.

3. The heat transfer medium according to claim 2, wherein
an amount of the water is equal to or greater than an amount of the methanol.

4. The heat transfer medium according to claim 2, wherein
a weight ratio of the methanol to the water is within a range of 35:65 to 50:50.

5. The heat transfer medium according to claim 1 further comprising
a boiling point elevation agent, wherein
the lower alcohol is the methanol.

6. The heat transfer medium according to claim 5, wherein
the boiling point elevation agent is soluble in both the water and the methanol, and
the boiling point elevation agent has a boiling point that is higher than a boiling point of a mixture of the water and the methanol.

7. The heat transfer medium according to claim 6, wherein
the boiling point elevation agent is at least one of an alcohol, an amine, an ether, or a carboxylic acid.

8. The heat transfer medium according to claim 5, wherein
a proportion of the boiling point elevation agent in the heat transfer medium is less than 50%.

9. The heat transfer medium according to claim 1, wherein
the lower alcohol is the ethanol.

10. The heat transfer medium according to claim 9, wherein
an amount of the water is equal to or greater than an amount of the ethanol.

11. The heat transfer medium according to claim 9, wherein
a weight ratio of the ethanol to the water is within a range of 35:65 to 50:50.

12. The heat transfer medium according to claim 2 further comprising
a rust inhibitor.

13. The heat transfer medium according to claim 1 further comprising
a non-ionic rust inhibitor.

14. The heat transfer medium according to claim 13, wherein
the non-ionic rust inhibitor is at least one of a silyl ether or a triazole compound.

15. The heat transfer medium according to claim 13, wherein
an amount of the water is equal to or greater than an amount of the lower alcohol.

16. The heat transfer medium according to claim 13, wherein
a weight ratio of the lower alcohol to the water is within a range of 35:65 to 50:50.

17. A heat transfer system using the heat transfer medium according to claim 1, the system comprising:
the refrigeration cycle device;
a heat transfer medium circuit through which the heat transfer medium circulates; and
a cooling heat exchanger configured to cool the heat transfer medium through heat exchange between the refrigerant and the heat transfer medium, wherein
the electric device is disposed in the heat transfer medium circuit, and
the heat transfer medium absorbs a heat from the electric device.

18. The heat transfer system according to claim 17, wherein
the heat transfer medium circuit is sealed.

19. A heat transfer system using the heat transfer medium according to claim 5, the system comprising:
the refrigeration cycle device;
a heat transfer medium circuit through which the heat transfer medium circulates;
a cooling heat exchanger configured to cool the heat transfer medium through heat exchange between the refrigerant and the heat transfer medium;
a high-temperature heat transfer medium circuit through which a high-temperature heat transfer medium circulates, the high-temperature heat transfer medium being the heat transfer medium having a temperature higher than that of the heat transfer medium flowing through the heat transfer medium circuit; and
a heating heat exchanger configured to heat the high-temperature heat transfer medium through heat exchange between the refrigerant and the high-temperature heat transfer medium.

20. The heat transfer system according to claim 19, wherein
the high-temperature heat transfer medium circuit is sealed.
